(19) United States
(12) Patent Application Publication
(10) Pub. No.: US 2005/0063145 A1
(43) Pub. Date: Mar. 24, 2005

(54) Computer system with rotatable display

(76) Inventors: Steven S. Homer, Tomball, TX (US); Paul J. Doczy, Cypress, TX (US); Ronald E. DeLuga, Spring, TX (US); Earl W. Moore, Cypress, TX (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/666,067

(22) Filed: Sep. 18, 2003

(51) Int. Cl. H05K 5/00

(52) U.S. Cl. 361/683

(57) ABSTRACT

A computer system comprises a base section and a display mounted about the base with first and second axes of rotation relative to the base, the first axis of rotation being proximate to and substantially parallel to an edge of the display and pivoting the display between pivoted positions, and the second axis of rotation being proximate to and substantially parallel to a centerline of the display regardless of the pivoted position of the display.

### BACKGROUND OF THE INVENTION

Notebook PCs and tablet PCs are well known. Both are used when a user needs to be mobile, out of the office, in the field or on the go. Additionally, notebook and tablet PCs have certain features or functions that distinguish these two types of PCs from each other. Notebook PCs, for example, include a keyboard and a pointing device for user input and may require the user to place the notebook PC on a firm surface for the most efficient two-handed user interaction. Tablet PCs, on the other hand, dispense with the need for a keyboard or a pointing device by including a touch-sensitive screen with which the user interfaces with the tablet PC by using a pen, or stylus, held in one hand. The tablet PC can be placed on a firm surface if such is available or cradled on the user's arm for greater mobility or use in cramped conditions.

Some PC manufacturers have combined the features and functions of both notebook PCs and tablet PCs into hybrid notebook/tablet PCs, having a base section and a rotatable display section. Thus, the user can convert the notebook/tablet PC to whichever configuration is needed in any situation. To convert between configurations, the display section is rotated to face either forward or backward, depending on the desired configuration, relative to the base section. When the user chooses to use the notebook/tablet PC as a notebook PC, for instance, the user rotates the display section to face forward, or toward the base section, and opens, or raises, the display section. When the user chooses to use the notebook/tablet PC as a tablet PC, on the other hand, the user rotates the display section to face backward, and closes the display section onto the base section.

The display section and base section of the notebook/tablet PCs are connected by a single clutch interface at which the display section rotates to face forward and backward and pivots to open and close. Notebook PCs, on the other hand, have display and base sections connected by two clutch interfaces at which the display section only pivots to open and close. The notebook/tablet PCs, thus, have less stability than do the notebook PCs at the connection between the display section and the base section. Additional means of stabilizing the display section are, therefore, included between the display section and the base section of the notebook/tablet PCs to stabilize the display section when it is not being rotated.

An option that is becoming more commonly available in notebook, tablet and notebook/tablet PCs is an antenna for wireless communication. For the notebook PCs and notebook/tablet PCs, the antenna is located in the display section, and emits a directional signal out of a back side of the display section. For the notebook PCs and in the notebook configuration of the notebook/tablet PCs, therefore, the signals radiate out the back side of the display section away from the PC. In the tablet configuration of the notebook/tablet PCs, however, the signals radiate out of the back side of the display section into the base section, since the back side of the display section faces toward the base section. In this manner, the signals of the antenna may be at least partially absorbed or interfered with by conductive material in the base section, thereby limiting the wireless communication capability of the notebook/tablet PCs in the tablet configuration.

Also, in the tablet configuration, relatively sharp corners of the display section project outward. In the notebook configuration, on the other hand, when the display section closes onto the base section, the sharp corners face inward adjacent the base section. Thus, when closed in the notebook configuration, smoothly curved corners of the display section project outward, which are more comfortable on the user's hands while holding the notebook/tablet PC. In the tablet configuration, on the other hand, the sharp corners make the notebook/tablet PCs much less comfortable to hold, even though it is in the tablet configuration in which the user is most likely to hold the notebook/tablet PC by hand or cradle it on an arm.

### SUMMARY OF THE INVENTION

According to a particular embodiment of the present invention, a computer system comprises a base, a frame and a display. The frame is mounted to the base to pivot between open and closed positions. The display rotates within the frame to face either inward or outward.

According to another embodiment of the present invention, a display section for a hybrid notebook/tablet computer system comprises a frame and a display. The display rotates within the frame, which is capable of being pivotally mounted to a base of the computer system.

Additionally, according to yet another embodiment, a method of using a computer system comprises providing the computer system with a display section closed against a base, the display section having a frame and a display within the frame, opening the display section by pivoting the frame away from the base, rotating the display from a first position to a second position relative to the frame and closing the display section by pivoting the frame toward the base.

### BRIEF DESCRIPTION OF THE DRAWINGS

FIG. 1 is a perspective view of a hybrid convertible notebook/tablet PC incorporating an embodiment of the present invention with a display in a closed position.

FIG. 2 is another perspective view of the hybrid convertible notebook/tablet PC shown in FIG. 1 with the display in an open position for use as a notebook PC.

FIG. 3 is another perspective view of the hybrid convertible notebook/tablet PC shown in FIGS. 1 and 2 with the display in the open position and partially rotated.

FIG. 4 is a perspective view of an alternative embodiment of the hybrid convertible notebook/tablet PC shown in FIGS. 1 and 2 with the display in the open position and partially rotated.

FIG. 5 is another perspective view of the hybrid convertible notebook/tablet PC shown in FIGS. 1-4 with the display in a partially open position and fully rotated.

FIG. 6 is another perspective view of the hybrid convertible notebook/tablet PC shown in FIGS. 1-5 with the display in the closed position and fully rotated for use as a tablet PC.

FIG. 7 is a cross-sectional view of the hybrid convertible notebook/tablet PC shown in FIGS. 1-6 with the display in the closed position and fully rotated for use as a tablet PC.

### DETAILED DESCRIPTION

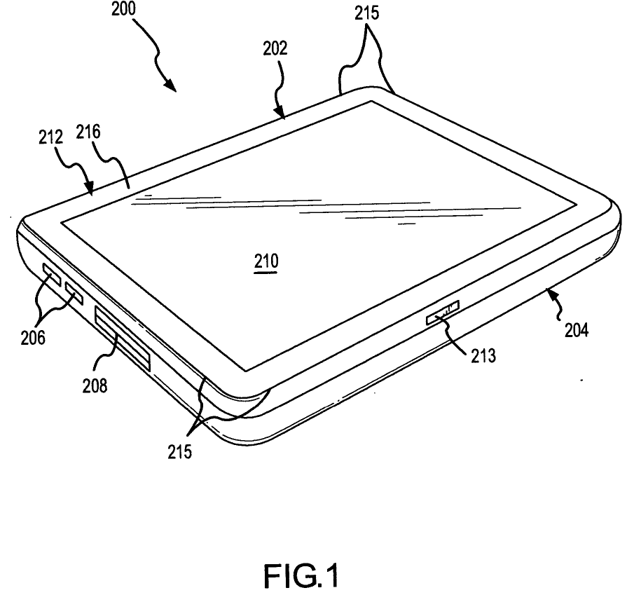

A computer system 200 incorporating an embodiment of the present invention is shown in FIG. 1. Although the computer system 200 is shown as a hybrid convertible notebook/tablet PC, the invention is not so limited, but may also be a hand-held computer, a palm computer, a personal digital assistant (PDA), a cell phone, etc. The computer system 200 includes a display section 202 and a base section 204. The base section 204 includes most of the electronic components of the computer system 200; as well as various ports 206 and slots 208 for adding on or inserting additional peripheral devices. The display section 202 includes a display 210 and a frame, or display holder, 212. The perimeter of the display 210 is partially or entirely surrounded by the frame 212. The frame 212 includes a latch release mechanism 213 for a latch that latches the display section 202 to the base section 204. The display 210 includes a display screen 214 on a viewing side of the display 210 that cannot be seen in FIG. 1, because, in the configuration shown, the display section 202 is closed onto the base section 204 and the display screen 214 is facing down, or inward.

The frame 212 also has rounded corner edges 215 along the periphery of the back, or outward, side 216 of the frame 212. The rounded corner edges 215 ensure the comfort of the user when the user is holding or carrying the computer system 200 in the closed configuration shown.

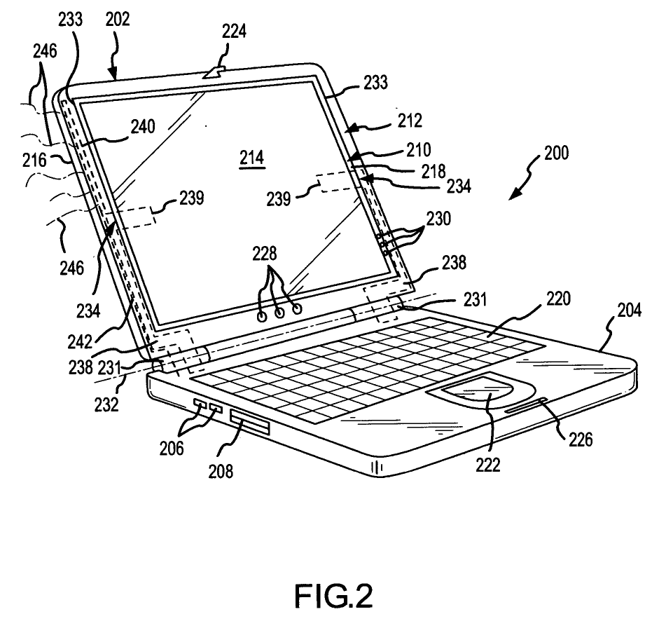

Upon opening the display section 202, as shown in FIG. 2, the display screen 214 on the viewing side of the display 210 is viewable within a border region 218 of the inwardly-facing display 210. Also viewable and accessible are a keyboard 220 and a pointing device 222 within the base section 204. In this configuration, the computer system 200 may be used as a notebook PC.

The open position shown for the display section 202 is exemplary only. The display section 202 typically has a range of open positions.

A latch hook 224 and hook receiver 226 for the latch are included in the inward side of the frame 212 and the keyboard side of the base section 204, respectively. In the closed position shown in FIG. 1, the latch hook 224 locks onto the hook receiver 226 to hold the display section 202 closed onto the base section 204.

A variety of control buttons 228 may be included on the side of the frame 212 that faces the base section 204. Additional control buttons 230 are preferably included at any appropriate location on the border region 218 of the display 210.

The frame 212 is hingedly connected to the base section 204 by clutch interfaces 231 (i.e. friction hinges). With the clutch interfaces 231, the frame 212 can pivot relative to the base section 204 along an edge axis of rotation 232 between the positions shown in FIGS. 1 and 2 and beyond. The clutch interfaces 231 provide sufficient friction force to hold the frame 212 and the display 210 in the open position shown in FIG. 2.

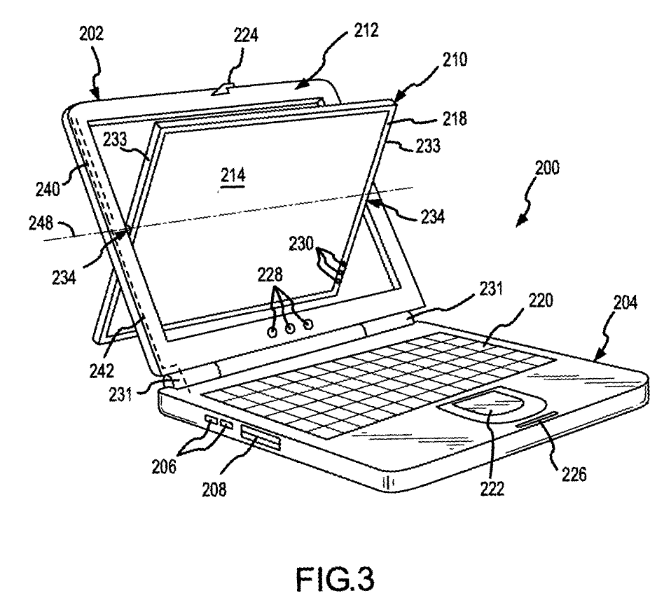

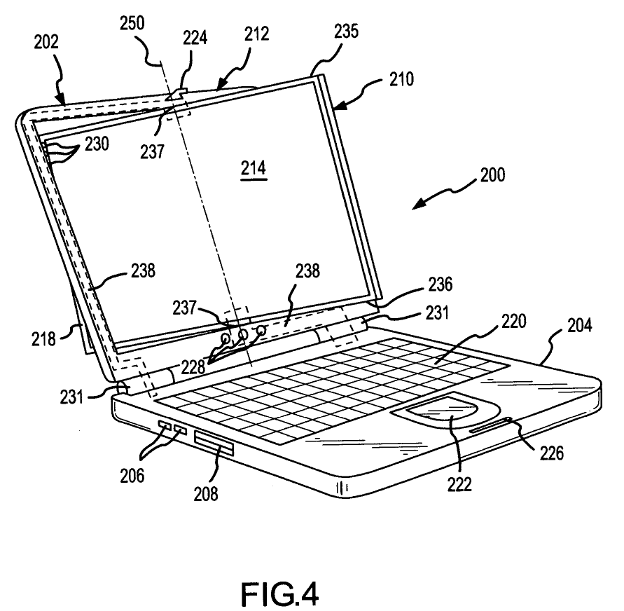

The display 210 is connected to the frame 212 by horizontally spaced hinges on opposing side edges 233 of th display 210 at locations 234, or by vertically spaced hinges on top and bottom edges 235 and 236 of the display 210 at locations 237 as described below with reference to FIG. 4. The hinges at 234 or 237 enable the display 210 to rotate within the frame 212 as described below with reference to FIGS. 3 and 4.

Electrical connection between the display 210 and the display electronics in the base section 204 is through one or more flat and wide ribbon connectors 238. The ribbon connectors 238 pass through the clutch interfaces 231, the frame 212 and the hinges at 234 or 237 (FIG. 4) in order to connect the electronics in the base section 204 to electrical connections at 239 in the display 210.

A wireless antenna 240 is preferably disposed at any appropriate location within the frame 212. The antenna 240 is connected to electronics in the base section 204 via a conductor 242 and is used for wireless communications. Although the antenna 240 may radiate signals to some degree in all directions, the strength of the signals is typically not completely symmetrical. Rather, the greatest percentage of the signal strength is substantially oriented in a predetermined direction. The antenna 240 is preferably situated to radiate the signals substantially in a predetermined direction that is primarily through a back side 216 of the frame 212 and away from the frame 212 and display section 202, as illustrated by radiation lines 246.

To convert the computer system 200 from the notebook PC configuration shown in FIG. 2 to a tablet PC configuration, the display 210 rotates within the frame 212 on the hinges at 234 along a horizontal centerline axis of rotation 248, as shown in FIG. 3. The frame 212 does not need to change positions while the display 210 is being rotated. Alternatively, the display 210 may rotate within the frame 212 on the hinges at 237 along a vertical centerline axis of rotation 250, as shown in FIG. 4.

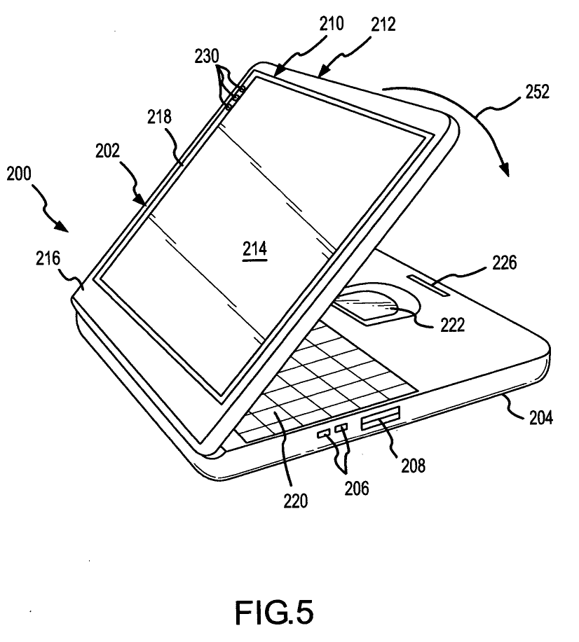

Upon being fully rotated, the display 210 faces outward from the back side 216 of the frame 212, as shown in FIG. 5. The control buttons 230 on the border region 218 of the display 210 are still accessible to the user in this configuration. Then, to complete the conversion of the computer system 200 to the tablet PC configuration, the display section 202 is pivoted down onto the base section 204 by pivoting the frame 212 in the direction of arrow 252.

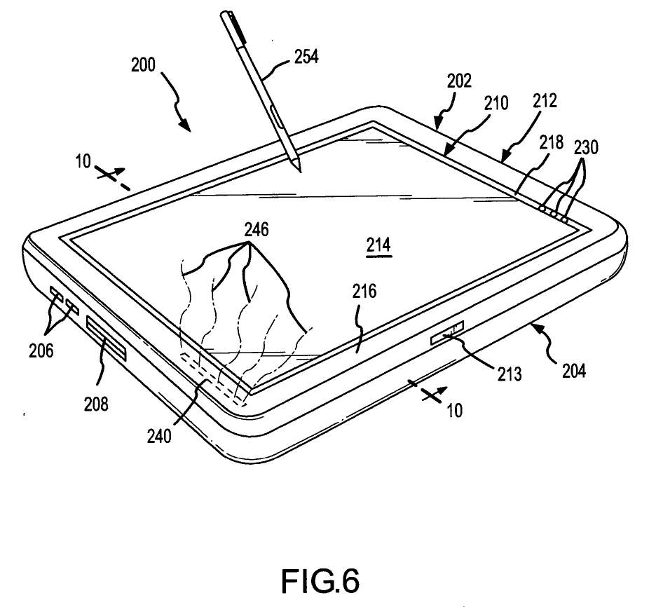

In the tablet PC configuration, the display screen 214 faces outward, as shown in FIG. 6. In this configuration, the frame 212 latches to the base section 204 with the latch hook 224 (FIGS. 2-4) and hook receiver 226 (FIG. 2-5). Additionally, since the computer system 200 serves as a tablet PC in this configuration, the display screen 214 is preferably touch-sensitive. Therefore, the user typically interfaces with the computer system 200 by writing on the display screen 214 with a pen, or stylus, 254. The user also has access to the control buttons 230 on the border region 218 of the display 210.

Furthermore, in the tablet PC configuration, the signal from the antenna 240 radiates primarily out the back side 216 of the frame 212 away from the computer system 200, instead of primarily into the base section, as described above in the prior art. Thus, regardless of the direction that the display 210 faces, the antenna 240 remains properly aligned for optimal radiation of signals away from the computer system 200.

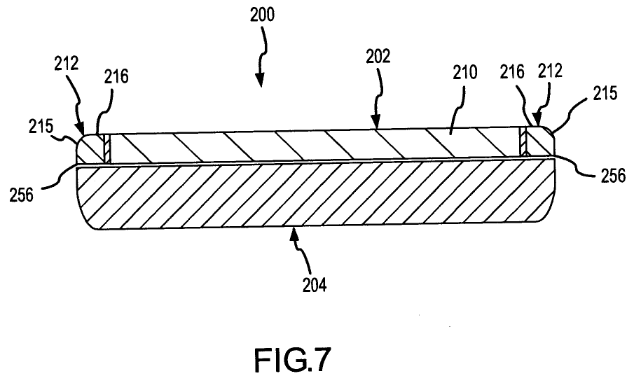

Additionally, in the tablet PC configuration, the rounded corner edges 215 of the back side 216 of the frame 212 face outward, as shown in the cross-section view in FIG. 7. Thus, in this configuration, the user is more comfortable when the user is holding or carrying the computer system 200, since relatively sharp corners 256 are not exposed to the user, as are the relatively sharp corners of the display section of the prior art hybrid convertible notebook/tablet PC described above.

In a particular embodiment of the computer system 200, the clutch interfaces 231 are preferably the same as or similar to the clutch interfaces that connect the base section and the display section of a prior art notebook PC. This embodiment of the computer system 200, thus, has the ability for either the prior art notebook PC display section or the new and improved display section 202 to be connected to the base section 204. In this manner, the same base section 204 can be used in manufacturing lines that produce either the prior art notebook PC or the new and improved computer system 200. A greater economy of scale and greater cost-savings may thus be achieved with this embodiment of the present invention. Additionally, a prior art notebook PC thus manufactured may be upgraded or converted into the computer system 200 by exchanging the prior art notebook PC display section for the new display section 202.

1. A computer system comprising:
a base;
a frame hingedly mounted on the base to pivot between open positions and a closed position; and
a display rotatably mounted in the frame to rotate between an inward facing position and an outward facing position.

2. A computer system as defined in claim 1 wherein:
the computer system can convertibly serve as a notebook personal computer and a tablet personal computer.

3. A computer system as defined in claim 1 wherein:
a viewing side of the display faces toward the base when the display is in the inward facing position and the frame is in the closed position.

4. A computer system as defined in claim 1 wherein:
a viewing side of the display faces away from the base when the display is in the outward facing position and the frame is in the closed position.

5. A computer system as defined in claim 1 further comprising:
an antenna disposed in the frame and operable to emit a signal substantially in a predetermined direction relative to the frame regardless of whether the display is in either one of the inward facing position and the outward facing position.

6. A computer system as defined in claim 5 wherein:
the frame has an outward side that faces away from the base;
the signal is emitted away from the outward side of the frame when the frame is in any one of the open positions and the closed position and the display is in either one of the inward facing position and the outward facing position.

7. A computer system as defined in claim 1 further comprising:
control buttons disposed in the display and user accessible when the frame is in the open position and the display is in the inward facing position and when the frame is in the closed position and the display is in the outward facing position.

8. A computer system as defined in claim 1 wherein:
the display has a perimeter; and
the frame substantially surrounds the perimeter of the display.

9. A computer system as defined in claim 1 wherein:
the display rotates about a horizontal axis relative to the frame.

10. A computer syst m comprising:
a base;
a display holder pivotally mounted on the base;
a display rotatably mounted on the display holder; and
first and second hinges on opposite edges of the display connecting the display to the display holder.

11. A computer system as defined in claim 10 wherein:
the display has a top edge, a bottom edge and two opposing side edges; and
the first and second hinges are disposed on the two opposing side edges of the display.

12. A computer system as defined in claim 10 wherein:
the display has a top edge, a bottom edge and two opposing side edges; and
the first and second hinges are disposed on the top edge and the bottom edge, respectively, of the display.

13. A computer system comprising:
a base;
a display holder mounted on the base;
a display mounted about the display holder and having two opposing edges and an electrical connection disposed near each opposing edge; and
two electrical paths, each connecting one of the electrical connections of the display through the display holder to the base.

14. A computer system as defined in claim 13 further comprising:
first and second clutch interfaces pivotally connecting the base and the display holder; and
first and second hinges rotatably connecting the display holder and the display at the two opposing edges;
and wherein:
a first one of the electrical paths passes through the first hinge and the first clutch interface between a first one of the opposing edges of the display and the base; and
a second one of the electrical paths passes through the second hinge and the second clutch interface between a second one of the opposing edges of the display and the base.

15. A computer system comprising:
a base; and
a display mounted about the base with first and second axes of rotation relative to the base, the first axis of rotation being proximate to and substantially parallel to an edge of the display and pivoting the display between pivoted positions, and the second axis of rotation being proximate to and substantially parallel to a centerline of the display regardless of the pivoted position of the display.

16. A computer system as defined in claim 15 wherein:
the second axis of rotation is along a horizontal centerline of the display extending between opposite edges of the display.

17. A computer system as defined in claim 15 wherein:
the second axis of rotation is along a vertical centerline of the display extending between a top and a bottom of the display.

18. A display section for a hybrid notebook/tablet computer system having a base, comprising:
a frame; and
a display rotatably mounted in the frame to rotate between first and second positions relative to the frame;
and wherein the frame is capable of being pivotally mounted to the base of the hybrid notebook/tablet computer system.

19. A display section as defined in claim 18 wherein:
the frame has an inward side and an outward side;
the display has a viewing side;
in the first position of the display relative to the frame, the viewing side of the display is proximate to the inward side of the frame; and
in the second position of the display relative to the frame, the viewing side of the display is proximate to the outward side of the frame.

20. A display section as defined in claim 19 wherein:
the first position of the display relative to the frame enables the hybrid notebook/tablet computer system to serve as a notebook personal computer upon mounting the display section to the base; and
the second position of the display relative to the frame enables the hybrid notebook/tablet computer system to serve as a tablet personal computer upon mounting the display section to the base.

21. A display section as defined in claim 18 further comprising:
an antenna disposed in the frame and, upon operation, emitting a signal substantially in a predetermined direction relative to the frame when the display is in either one of the first and second positions.

22. A display section as defined in claim 18 further comprising:
control buttons disposed in the display;
and wherein:
the display has a viewing side; and
the control buttons are accessible on the viewing side of the display.

23. A display section as defined in claim 18 wherein:
the display has a perimeter; and
the frame substantially surrounds the perimeter of the display.

24. A display section as defined in claim 18 wherein:
the display rotates about a horizontal axis relative to the frame.

25. A method of using a computer system comprising:
providing the computer system with a display section closed against a base, the display section having a frame and a display within the frame;
opening the display section by pivoting the frame away from the base,
rotating the display from a first position to a second position relative to the frame; and
closing the display section by pivoting the frame toward the base.
